(19) United States
(12) Patent Application Publication
(10) Pub. No.: US 2005/0186803 A1
(43) Pub. Date: Aug. 25, 2005

(54) Method of manufacturing semiconductor device

(76) Inventors: Kaori Umezawa, Kamakura-shi (JP); Hiroshi Tomita, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/060,567

(22) Filed: Feb. 18, 2005

(30) Foreign Application Priority Data
Feb. 20, 2004 (JP) 2004-044192

(51) Int. Cl. H01L 21/00; H01L 21/84; H01L 21/8234; H01L 21/8238

(52) U.S. Cl. 438/745; 438/275; 438/231; 438/258

(57) ABSTRACT

A method of manufacturing a semiconductor device includes selectively forming a photoresist film on an insulating film formed on a surface of a underlying semiconductor region such that the photoresist provides a masked surface region and an exposed surface region for the insulating film, and selectively removing that portion of the insulating film which corresponds to the exposed surface region to expose the underlying semiconductor region. Sulfuric acid is applied to a plane including a surface of the photoresist film, with the surface of the underlying semiconductor region being exposed and the photoresist film is removed with the sulfuric acid.

### CROSS-REFERENCE TO RELATED APPLICATIONS

This application is based upon and claims the benefit of priority from prior Japanese Patent Application No. 2004-044192, filed Feb. 20, 2004, the entire contents of which are incorporated herein by reference.

### BACKGROUND OF THE INVENTION

1. Field of the Invention

The present invention relates to a method of manufacturing a semiconductor device.

2. Description of the Related Art

Vigorous research is being conducted nowadays in an attempt to develop a semiconductor device having both a memory and a logic element embedded therein in compliance with the demands for high integration and high performance of the semiconductor device. In designing such a semiconductor device, it is necessary to form a plurality of gate insulating films differing from each other in thickness. For example, in order to form two gate insulating films differing from each other in thickness on a semiconductor substrate, an insulating film having a relatively large thickness may be formed on a semiconductor substrate. A photoresist film is formed on the insulating film in a manner to selectively expose that portion of the insulating film on which a thin gate insulating film is to be formed. Then, the exposed portion of the insulating film is etched so as to expose the surface of the semiconductor substrate. Finally, the photoresist film is removed, and a thin gate oxide film is formed by thermal oxidation on the exposed surface of the semiconductor substrate.

Ashing or SPM (mixed solution of sulfuric acid and hydrogen peroxide) has been used to remove the photoresist film. However, since oxygen used in the ashing treatment and hydrogen peroxide contained in SPM act an oxidizing agent, a thin chemical oxide film having a thickness of about 0.8 nm to about 2 nm is formed on the exposed surface of the silicon substrate in removing the photoresist film masking the thick gate insulating film. Where the gate insulating film to be formed has a thickness not smaller than 1.5 nm, a gate insulating film having a sufficiently high quality can be formed even if the thermal oxidation treatment is carried out without removing the chemical oxide film. However, in the high speed semiconductor device of the next generation, a thin gate insulating film having a thickness smaller than 1.2 nm is required. If a chemical oxide film is formed to a thickness of 1.2 nm or more in the removing step of the photoresist film, there is no room for an additional insulating film to be formed by, for example, the thermal oxidation. It follows that a reliable insulating film cannot be obtained. It may be possible to remove the photoresist film by using an organic solvent. However, an organic solvent contains metal impurities at a relatively high concentration. Since the gate insulating film, in particular, is deteriorated by the contamination with the metal, it is undesirable to use an organic solvent.

It is also possible to remove the chemical oxide film by the treatment with a hydrofluoric acid-based etchant before formation of the thin gate oxide film. However, the thick gate oxide film is also etched in this case. What should be noted is that the etching of the thick gate oxide film is locally promoted by the defect in the thick gate oxide film, giving rise to pin holes in the thick gate oxide film, with the result that a poor initial breakdown voltage tends to be brought about.

A measure for overcoming the problem noted above is disclosed in Japanese Patent Disclosure (Kokai) No. 2001-196464. It is disclosed in this patent document that a thick gate oxide film formed is subjected to a plasma nitriding treatment so as to improve the resistance of the film to the etching with a hydrofluoric acid-based etchant.

Even in the case of the technology disclosed in the patent document quoted above, however, the thickness of the thick gate oxide film is decreased by 5 nm or less by the treatment with the hydrofluoric acid-based etchant. If the gate oxide film is etched, the insulating properties of the gate oxide film are rendered poor even if the etching amount is only several angstroms (Å), compared with the gate insulating film that is not etched.

The chemical oxide film that is formed in removing the photoresist film also remains to be a problem in manufacturing a NAND type flash memory device. To be more specific, in manufacturing a NAND type flash memory device, a polysilicon film, which is commonly used in a memory cell region, is connected to an underlying polysilicon gate electrode formed in a peripheral circuit region and covered with an insulating film. For connecting the polysilicon film to the underlying polysilicon gate electrode, the insulating film covering the underlying polysilicon gate electrode is selectively removed for forming an opening under the state that the insulating film is masked by a photoresist film. When the photoresist film is removed in the subsequent step, a chemical oxide film is formed relatively thick as in the prior art described above so as to increase the resistance of the polysilicon gate electrode.

### BRIEF SUMMARY OF THE INVENTION

According to an aspect of the present invention, there is provided a method of manufacturing a semiconductor device, comprising: selectively forming a photoresist film on an insulating film formed on a surface of a underlying semiconductor region such that the photoresist provides a masked surface region and an exposed surface region for the insulating film; selectively removing that portion of the insulating film which corresponds to the exposed surface region to expose the underlying semiconductor region; applying sulfuric acid to a plane including a surface of the photoresist film, with the surface of the underlying semiconductor region being exposed; and removing the photoresist film with the sulfuric acid.

### BRIEF DESCRIPTION OF THE SEVERAL VIEWS OF THE DRAWING

FIGS. 1A to 1F are cross sectional views schematically showing collectively a method of manufacturing a semiconductor device according to an embodiment of the present invention;

FIGS. 2A to 2E are cross sectional views schematically showing collectively a method of manufacturing a NAND type flash memory according to another embodiment of the present invention;

FIG. 3 schematically shows a construction of a apparatus for manufacturing a semiconductor device that is used for manufacturing a semiconductor device according to an embodiment of the present invention;

FIG. 4 is a graph showing the relationship between the thickness of the chemical film and the temperature, in the cases where the photoresist film is removed by SPM and by sulfuric acid;

FIG. 5 is a graph showing the relationship between the sulfuric acid concentration and the temperature in respect of the removal of the photoresist film;

FIG. 6 is a graph showing the uniformity in the thickness of the oxide film, in the cases where the chemical oxide film is washed with water supplied from a fixed central nozzle and where water supplied from a swinging nozzle is used for the washing; and

FIG. 7 is a graph showing the relationship between the number of wafers having a photoresist which are immersed in a sulfuric acid-circulating tank and the thickness of chemical oxide film formed on an exposed silicon wafer in the case where the wafers having a photoresist and the exposed silicon wafer are placed together in the tank.

### DETAILED DESCRIPTION OF THE INVENTION

Embodiments of the present invention will now be described more in detail.

A method of manufacturing a semiconductor device according to an aspect of the present invention comprises selectively forming a photoresist film on an insulating film formed on the surface of a underlying semiconductor region such that the photoresist provides a masked surface region and an exposed surface region for the insulating film, and selectively removing that portion of the insulating film which corresponds to the exposed surface region to selectively expose the underlying semiconductor region. After the surface of the underlying semiconductor region is selectively exposed, sulfuric acid is applied to a plane including the surface the photoresist film, with the surface the underlying semiconductor region being exposed, and the photoresist is dissolved and removed by the sulfuric acid. In this case, the sulfuric acid used to dissolve and remove the photoresist is not re-used. In one embodiment of the present invention, the semiconductor wafer is not immersed in a large amount of sulfuric acid.

In one embodiment, the underlying semiconductor region includes a semiconductor substrate and a polysilicon film formed on a semiconductor substrate. The polysilicon film may be formed on a semiconductor substrate with a gate insulating film interposed therebetween, and may provide a gate electrode. In one embodiment, the insulating film includes a gate insulating film, and an ONO (oxide film/nitride film/oxide film) stack which is formed on a polysilicon film. Further, the photoresist may be the one which generally used in the art, such as a novolak resin resist.

In an embodiment of the present invention, the underlying semiconductor region may provided by a semiconductor substrate, and the insulating film to be masked by a photoresist film may be provided by a thick gate insulating film, e.g., a gate oxide film. In this case, a method of manufacturing a semiconductor device according to this embodiment may further comprise forming a second insulating film smaller in thickness than the thick gate insulating film on the exposed surface of the semiconductor substrate after removal of the photoresist film.

In another embodiment of the present invention, the underlying semiconductor region may be provided by a semiconductor film, such as a polysilicon gate electrode layer formed on the semiconductor substrate with a gate insulating film interposed therebetween. Also, the insulating film formed on the semiconductor layer may be provided by an ONO (oxide film/nitride film/oxide film) stack. A method according to this embodiment may further comprise forming a semiconductor film (polysilicon film) that is in contact with the exposed polysilicon film (underlying semiconductor region) after removal of the photoresist.

The sulfuric acid used in one embodiment may have a concentration not lower than 85% by weight. Also, removal of the photoresist film by sulfuric acid may be carried out at temperatures of from room temperature (20° C.) to about 130° C. In removing the photoresist by sulfuric acid, when wafers having the photoresist are placed such that the photoresist is immersed in sulfuric acid contained in a container such as a tank while circulating the sulfuric acid inside and outside the tank, the thickness of a chemical oxide film formed on the exposed surface of the underlying semiconductor region, though the mechanism has not been clarified in detail. Accordingly, in one embodiment, the photoresist is dissolved and removed by treating the surface of the photoresist without re-using or recycling the sulfuric acid used. In one embodiment of the invention, for example, sulfuric acid may be flowed down to the photoresist from an upper nozzle. In this case, the sulfuric acid may be applied solely to the plane including the surface of the photoresist. It is possible to allow sulfuric acid to flow downward from above at a flow rate of about 500 mL/min to about 2,000 mL/min for about 5 seconds to about 60 seconds. In this case, the semiconductor wafer may be rotated, while the sulfuric acid is flowed downward onto substantially the center of the rotating semiconductor wafer, and the photoresist dissolved by contact with sulfuric acid may be centrifugally separated from the semiconductor wafer. In removing the photoresist by sulfuric acid, a chemical oxide is formed on the exposed surface of the underlying semiconductor region. The thickness of the chemical oxide film thus formed is not larger than 0.6 nm. The succeeding process step can be carried out without removing the chemical oxide film formed by the treatment with sulfuric acid. Incidentally, the removal of the photoresist film by sulfuric acid is usually carried out by single wafer processing.

When the photoresist film is removed by sulfuric acid according to one embodiment, the impurities and the metal contaminants in the photoresist are also removed.

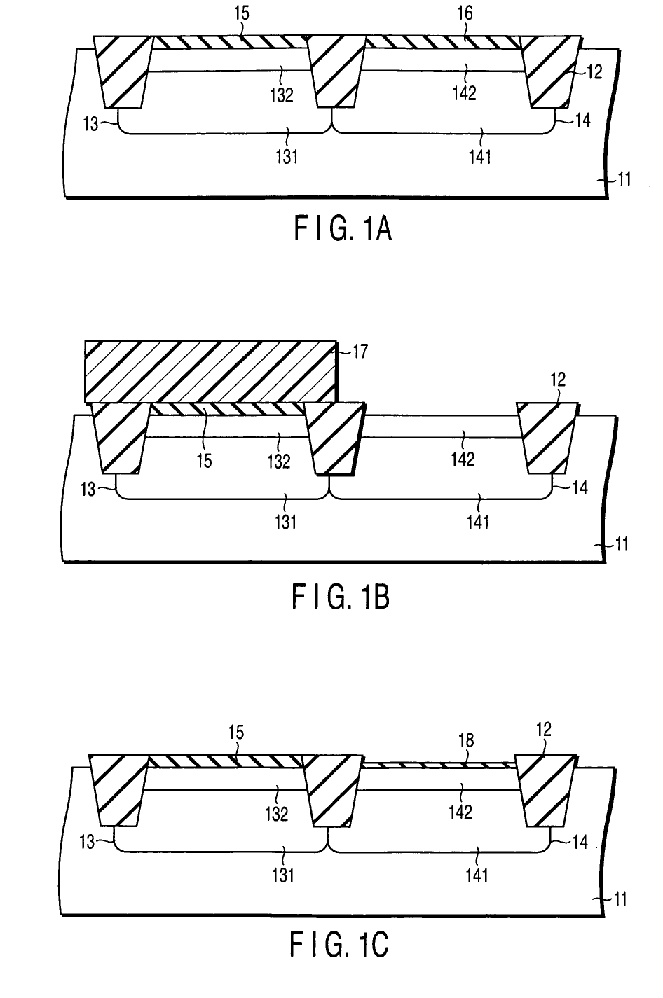

FIGS. 1A to 1F are cross sectional views collectively showing a method of manufacturing a semiconductor device according to a first embodiment of the present invention.

The method according to the first embodiment is directed to the manufacture of a semiconductor device including a plurality of gate insulating films differing from each other in thickness. The method comprises forming a thick first insulating film on a semiconductor substrate, selectively forming a photoresist film on the first insulating film such that the photoresist provides a masked surface region and an exposed surface region for the insulating film, removing that portion of the first insulating film which corresponds to the exposed surface region so as to selectively expose the surface of the semiconductor substrate, removing the photoresist film by using sulfuric acid with the exposed surface region of the semiconductor substrate being exposed, and forming a second gate insulating film smaller in thickness than the first insulating film on the exposed surface region of the semiconductor substrate.

More specifically, isolation regions 12 are formed in a semiconductor substrate 11 such as a silicon substrate by an ordinary method such as an STI (Shallow Trench Isolation) method, defining element formation regions 13 and 14, as shown in FIG. 1A. Then, a p-type impurity is ion-implanted into the element formation regions 13 and 14, forming p-type wells 131 and 141 in the element formation regions 13 and 14, respectively, followed by ion implantation of an n-type impurity into the element formation regions 13 and 14, forming n-type wells 132 and 142 in the element formation regions 13 and 14, respectively. Further, thermal oxide films (thick first insulating films) 15 and 16 each having a thickness of, for example, 3 nm are formed on the surfaces of the n-type wells 132, 142, respectively, by an ordinary heat treatment.

Next, the surface of the element formation region 13 alone is masked by a photoresist film 17, and the thermal oxide film 16 on the element formation region 14 is removed, as shown in FIG. 1B. The thermal oxide film 16 can be removed by using a wet etchant that does not oxidize the surface of the element formation region 14, such as a buffered hydrofluoric acid (a mixed solution of ammonium fluoride and hydrofluoric acid) containing a surfactant or a diluted hydrofluoric acid. Also, a dry process can be employed for removing the thermal oxide film 16 as far as the surface of the element formation region 14 is not oxidized. After removal of the thermal oxide film 16, the surface of the semiconductor substrate can be washed with deionized water.

Then, sulfuric acid is applied to the plane including the surface of the photoresist film 17, as described previously, and the photoresist is removed by the applied sulfuric acid. A chemical oxide film 18 (see FIG. 1C) formed on the surface of the element formation region 14 by the sulfuric acid has a thickness of smaller than 1 nm, particularly 0.6 nm or less. Sulfuric acid can be brought into contact with the photoresist film 17 by dripping sulfuric acid onto the central portion of the semiconductor substrate for about 10 seconds while rotating the semiconductor substrate.

After removal of the photoresist film 17, the surfaces of the element formation regions are washed. The washing can be performed by dripping a washing solution from a nozzle onto the semiconductor substrate. As the washing liquid, for example, water (particularly deionized water; including warm water), a diluted hydrochloric acid, an alkali aqueous solution, or an aqueous solution of carbonic acid can be used. In general, the washing can be performed by dripping the washing solution toward the central portion of the semiconductor substrate while rotating the semiconductor substrate. In the case of using cold water as the washing liquid, it has been found that, if cold water is dripped from the nozzle that is held stationary above the central portion of the semiconductor substrate, the thickness of the chemical oxide film positioned right under the nozzle is increased. In order to suppress the increase in thickness of the chemical oxide film, it is desirable to drip cold water from a nozzle that is swung horizontally in the space above the semiconductor substrate between the central portion and the edge portion of the semiconductor substrate. Incidentally, sulfur ions attached to the surface of the element formation region 14 after removal of the photoresist film by sulfuric acid can be removed by washing with a warm water (about 40° C. to 80° C.).

Then, the structure shown in FIG. 1C is subjected to an oxidizing treatment, such as a rapid thermal oxidation (RTO), oxidation under an oxygen atmosphere diluted with a nitrogen gas, a steam oxidation or a radical oxidation, without removing the chemical oxide film 18, so as to form an oxide film 19 (including the chemical oxide) having a thickness of, for example, 0.8 nm as shown in FIG. 1D. Then, the oxide film 15 and the oxide film 19 are subjected to a plasma nitriding treatment to nitride the surface regions of the oxide films 15 and 19 to convert the oxide films 18 and 19 into oxynitride films, providing gate insulating films 20 and 21, as shown in FIG. 1E. Incidentally, the gate insulating film 21 can be formed not only by thermal oxidation and the nitriding treatment as described above, but also by deposition, on the chemical oxide film 18, of a high-k material such as hafnium oxide or hafnium silicate.

After formation of the gate insulating films 20 and 21, a polysilicon film 22 is formed first on the entire surface by CVD method to a thickness of, for example, 170 nm, in accordance with an ordinary CMOS process, as shown in FIG. 1E.

Next, the polysilicon film 22 is processed by the photolithography technique to form gate electrodes 221 and 222, followed by forming LDD (Lightly Doped Drain) regions 23 and side walls 24 and subsequently performing ion implantations to form source and drain regions, the recrystallization annealing, and formation of silicide films 25, as shown in FIG. 1F. Finally, formation of an interlayer insulating film, formation of contact holes, and wiring process are carried out.

In the first embodiment described above, the STI region is formed first in the semiconductor substrate. However, it is possible to form, for example, a trench capacitor in the first step, followed by forming the STI regions and the gate oxide film in the order mentioned in the case of manufacturing a semiconductor device having an embedded DRAM.

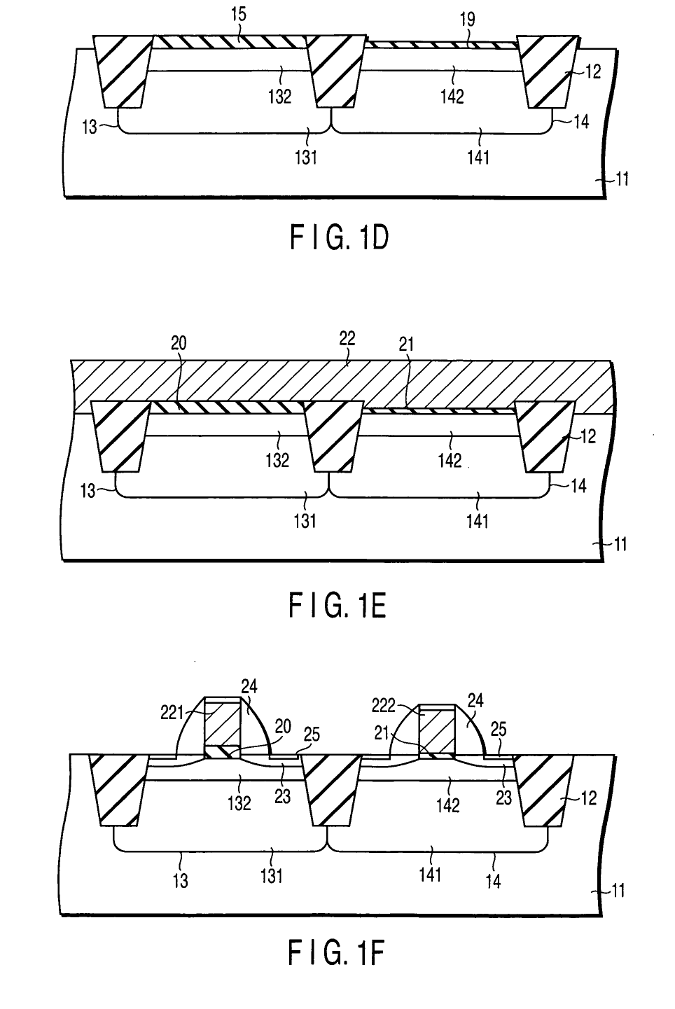

A second embodiment of the present invention, which is applied to manufacture of a NAND type flash memory, will now be described with reference to FIGS. 2A to 2E.

Referring to FIG. 2A first, an ion implantation is applied to a silicon substrate 31 to form a well region (not shown), followed by forming a first oxide film 32 having a thickness of, for example, 35 nm on the entire surface of the substrate 31. Then, the surface of a peripheral circuit region 311, in which a peripheral circuit transistor is to be formed, is masked by a photoresist (not shown). Under this state, that portion of the oxide film 32 which is positioned on the surface of a memory cell array region 312, in which a memory cell is to be formed, is removed by using a hydrofluoric acid etchant to expose selectively the surface of the underlying semiconductor substrate 31. Then, the photoresist mask is removed with SPM, followed by forming a second oxide film 33 smaller in thickness than the first oxide film 32 to a thickness of, for example, 8 nm on the memory cell array region 312 as shown in FIG. 2B. Thereafter, a polysilicon film 34 forming a floating gate is formed to a thickness of, for example, 50 nm on the entire surface of the semiconductor wafer.

After formation of the polysilicon film 34, a silicon nitride film 35 and a silicon oxide film 36, which are collectively used as a mask, are formed successively on the entire surface in order to form STI regions, followed by forming a photoresist film (not shown) on the silicon oxide film 36 by an ordinary method and subsequently forming holes in the photoresist film. Then, holes extending through the silicon oxide film 36, the silicon nitride film 35, the polysilicon film 34 and the oxide films 32 and 33 are formed in the positions corresponding to the holes formed in the photoresist film, followed by removing the photoresist mask. Further, the substrate 31 is subjected to a reactive ion etching with the remaining silicon oxide film 36 and the silicon nitride film 35 used as a mask to form in the substrate 31 holes in which STI regions are to be formed. Then, an STI material layer is formed in each of the holes formed in the semiconductor substrate 31 so as to form STI regions 37 and 38, followed by planarizing the STI regions 37 and 38 by CMP.

Next, the remaining silicon oxide film 36 and silicon nitride film 35 are removed together with the upper portions of the STI regions 37 and 38 corresponding in height to the silicon oxide film 36, followed by forming a polysilicon film 39 to a thickness of, for example, 300 nm on the entire surface and subsequently applying a planarization treatment, as shown in FIG. 2C. Then, a photoresist film (not shown) is formed on the surface of the peripheral circuit region 311, and holes are formed in those regions of the photoresist film which correspond to the STI regions 38. Thereafter, the upper portions of the STI regions 38 are etched with a hydrofluoric acid etchant until the upper surfaces of remaining STI regions 38 are made flush with the upper surface of the polysilicon film 34. Then, the photoresist mask is removed. Next, an ONO (oxide film/nitride film/oxide film) stack 40 is formed to a thickness of, for example, 15 nm on the entire surface, followed by forming a polysilicon film 41 to a thickness of, for example, 30 nm on the ONO stack 40.

The formation of the peripheral circuit transistor alone will be described for brevity in the following in respect of the process steps following the steps described above in conjunction with FIG. 2C.

As shown in FIG. 2D, a photoresist film 42 is formed on the polysilicon film 41, followed by selectively forming a hole 421 in that portion alone of the photoresist film 42 which corresponds to the peripheral circuit region. Then, a reactive ion etching is applied through the hole 421 so as to form a hole extending through the polysilicon film 41 and the ONO stack 40 on the peripheral circuit region 311, partially exposing the surface of the underlying polysilicon film 39. Further, the photoresist film 42 is removed by the treatment with sulfuric acid in accordance with the embodiments described above.

Incidentally, the photoresist film 42 can be removed by the ashing treatment, followed by the treatment with SPM and an alkaline solution. In this case, however, the ashing treatment causes a chemical oxide film to be formed to a thickness of about 2 nm on the polysilicon film 39 so as to increase the resistance of the polysilicon gate. Such being the situation, the entire surface including the ONO stack formed in the memory cell array region is masked by a second photoresist film after removal of the photoresist film 42 by the treatment with SPM and with an alkaline solution that is carried out after the ashing treatment. Then, a hole corresponding to the hole 421 formed in the photoresist film 42 is formed in the second photoresist film, followed by removing the chemical oxide film formed on the polysilicon film 39 by the treatment with a dilute hydrofluoric acid. After removal of the chemical oxide film noted above, the second photoresist film can be removed by the treatment with sulfuric acid, which is carried out in accordance with an embodiment of the present invention.

After removal of the second photoresist film, a polysilicon film 43 commonly included in the memory cell and the peripheral transistor is formed as shown in FIG. 2E. Then, a WSi film and a silicon nitride film are formed by an ordinary method so as to form a gate. Further, source and drain regions are formed by ion implantations, thereby manufacturing an ordinary transistor. The resistance of the gate thus formed can be low stably.

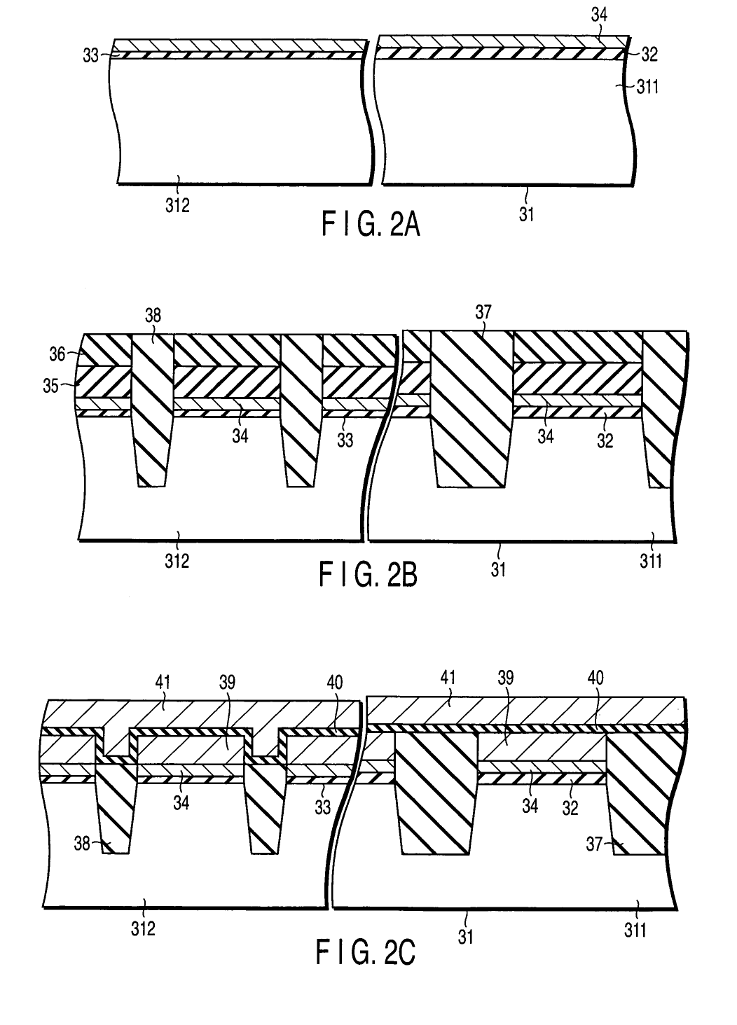

FIG. 3 schematically shows the construction of an apparatus 50 which can be used for manufacturing a semiconductor device according to one embodiment of the present invention. The apparatus 50 comprises a horizontally swinging nozzle for dripping water while being swung, and a support member 53 for supporting a semiconductor substrate 52. The semiconductor substrate 52 supported by the support member 53 comprises a thick first insulating film (15, 16) that is obtained as described previously in conjunction with FIG. 1A and a photoresist film (17) selectively formed on the first insulating film 15 such that it provides a masked surface region (the surface of the element formation region 13) and exposed surface region (the surface of the element formation region 14). The support member 53 can be housed in a washing chamber 51. A rotary shaft 54 for rotating the support member 53 extends through the bottom portion of the chamber 51. The rotary shaft 54 can be rotated by a rotary driver 55 such as a motor, with the result that the support member 53 and the semiconductor substrate 52 supported by the support member 53 can also be rotated in accordance with rotation of the rotary shaft 54.

A nozzle N1 for dripping a wet etchant for etching the first insulating film 16 positioned in the element formation region 14 is formed to extend from above the center of the washing chamber 51 into the washing chamber 51. The wet etchant supplied from a wet etchant supply source 56 is dripped from the nozzle N1 onto substantially the center of the semiconductor substrate 52. Also, a nozzle N2 for dripping sulfuric acid for removing the photoresist (17) is provided to extend from above the center of the washing chamber 2 into the washing chamber 51. Sulfuric acid supplied from a sulfuric acid supply source 57 is dripped from the nozzle N2 onto substantially the center of the semiconductor substrate 52 so as to dissolve and remove the photoresist (17).

The apparatus 50 is also provided with a water wash nozzle N3 for washing the surface of the semiconductor substrate 52 after removal of the photoresist (17) by the treatment with sulfuric acid. The water wash nozzle N3 can be swung within the free space above the semiconductor substrate 52 between the central portion and the outer peripheral portion of the semiconductor substrate 52. Water supplied from a water supply source 58 is dripped from the water wash nozzle N3. Needless to say, a slit forming a swinging route of the water wash nozzle N3 is formed in the upper wall of the washing chamber 51. It is also possible to drip warm water through the nozzle N3.

An additional water supply source 59 can be mounted on the apparatus 50 to wash the surface of the semiconductor substrate 52 with water after removal of the first insulating film with a wet etchant. The water supply source 59 can be connected to the wet etchant dripping nozzle N1 via a pipe P1. Further, an additional sulfuric acid supply source 60 can be mounted on the apparatus 50 to dissolve and remove the photoresist (17). The additional sulfuric acid supply source 60 can be connected to the swinging nozzle N3 via a pipe P2.

In operation, a wet etchant supplied from the wet etchant supply source 56 is dripped from the nozzle N1 onto the semiconductor substrate 52 so as to etch the insulating film (16). Then, water supplied from the water supply source 59 through the pipe P1 is dripped from the nozzle N1 onto the semiconductor substrate 52 so as to wash the surface of the semiconductor substrate 52 with water. After washing with water, sulfuric acid supplied from the sulfuric acid supply source 57 is dripped from the nozzle N2 onto the semiconductor substrate 52 so as to dissolve and remove the photoresist (17). In this step, the sulfuric acid supplied from the additional sulfuric acid supply source 60 through the pipe P2 may be dripped from the swinging nozzle N3 onto the semiconductor substrate 52. After removal of the photoresist film (17), the water supplied from the water supply source 58 is dripped from the swinging nozzle N3 onto the semiconductor substrate 52 to wash the oxide film including the chemical oxide film (18) with water. Incidentally, the switching valves, etc. for switching the dripping of the liquid materials supplied from the supply sources are not shown in FIG. 3 for brevity.

### EXAMPLE 1

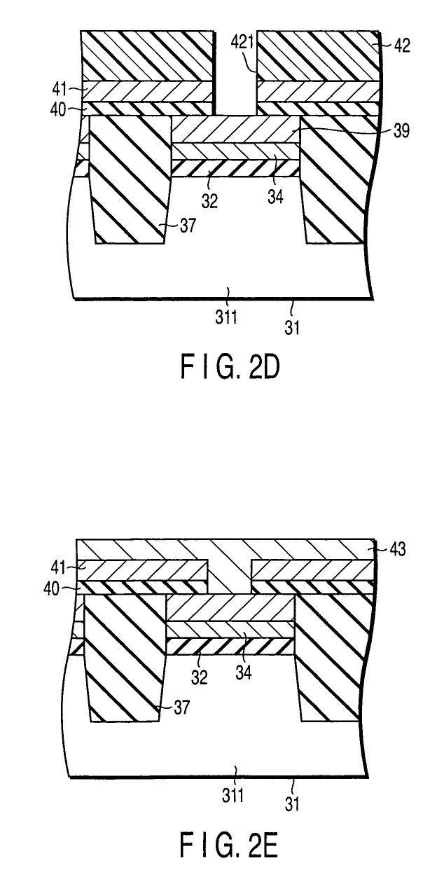

The photoresist film 17 was formed and, then, the oxide film 16 was removed with a diluted hydrofluoric acid in accordance with the process steps described previously with reference to FIGS. 1A and 1B. Further, after the water wash, the photoresist film 17 having a thickness of about 1 μm was removed with SPM or sulfuric acid (concentration: 96%) at various temperatures so as to measure the thickness of the chemical oxide film formed on the element formation region 14. Incidentally, SPM or sulfuric acid was dripped from the nozzle onto the surface of the semiconductor substrate for 10 seconds. FIG. 4 is a graph showing the results. Line a shown in FIG. 4 relates to SPM, and line b relates to sulfuric acid.

As apparent from FIG. 4, the thickness of the chemical oxide film was not smaller than 0.8 nm in the case of using SPM even if the process temperature was lowered from 130° C. to 60° C. The chemical oxide film formed in the case of using SPM was thermally oxidized under a gaseous atmosphere containing an oxygen gas, with the result that the thickness of the resultant oxide film was found to be 1 to 1.5 nm.

On the other hand, in the case of using sulfuric acid, the thickness of the chemical oxide film was only about 0.6 nm even at the process temperature of 130° C. and was only about 0.2 nm at the process temperature of 70° C. When the chemical oxide film was thermally oxidized under a gaseous atmosphere containing an oxygen gas, the thickness of the resultant oxide film was found to be 0.8 nm in each of the two cases, i.e., the process temperatures of 130° C. and 70° C. noted above. Therefore, a gate insulating film smaller in thickness than 1.2 nm can be realized in the case of removing the photoresist film with sulfuric acid.

### EXAMPLE 2

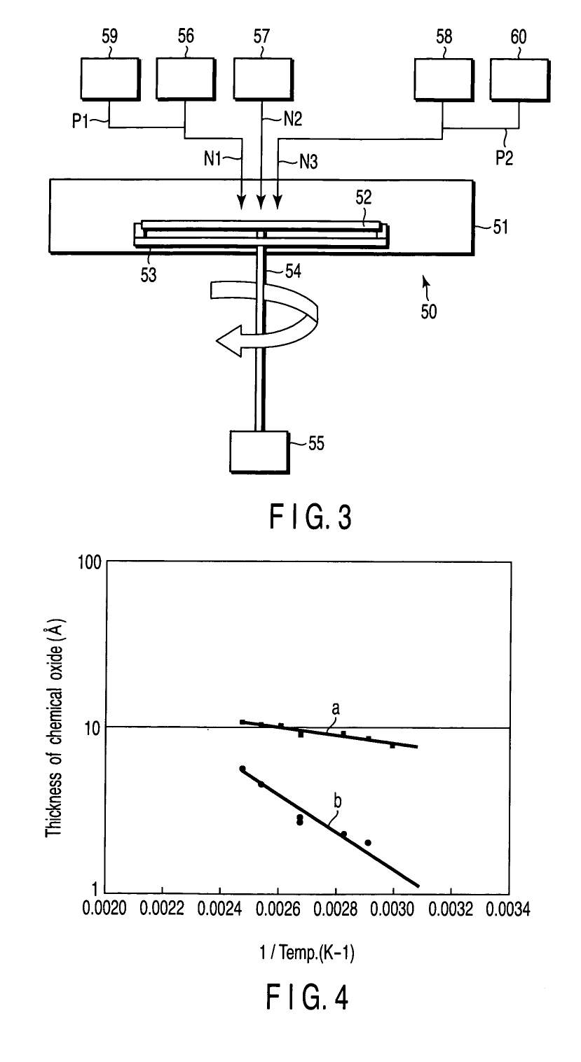

In this Example, capability of dissolving/peeling the photoresist film by sulfuric acid was examined. Specifically, the photoresist film 17 was formed and, then, the oxide film 16 was removed with a diluted hydrofluoric acid in accordance with the process steps described previously with reference to FIGS. 1A and 1B. Further, after the water wash, the photoresist film 17 was treated with sulfuric acid of various concentrations (75, 80, 85, 90, 95%) at various temperatures so as to examine the dissolving of the photoresist. FIG. 5 is a graph showing the results. The mark “◯” in FIG. 5 denotes that the photoresist was completely dissolved by sulfuric acid, the mark “Δ” denotes that the photoresist was dissolved by sulfuric acid and, at the same time, was partly peeled, and the mark “X” denotes that the photoresist was not dissolved by sulfuric acid and was peeled. It should be noted that the peeling of the photoresist causes the particle generation. As apparent from FIG. 5, it is desirable to use sulfuric acid having a concentration not lower than 95% at room temperature, a concentration not lower than 90% at temperatures not lower than 90° C., and a concentration not lower than 85% at temperatures not lower than 110° C.

### EXAMPLE 3

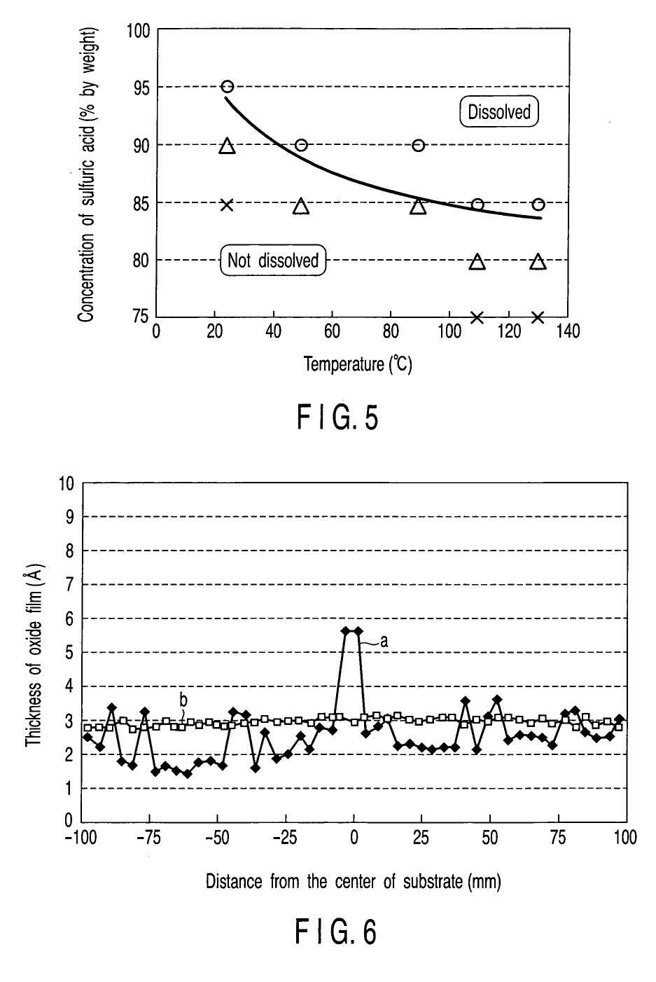

Thickness of the oxide film was measured, covering the cases where the chemical oxide film formed on the element formation region 14 after removal of the photoresist film with sulfuric acid in Example 1 was washed with water dripped from only above the center of the semiconductor substrate and where the chemical oxide film noted above was washed with water dripped from the swinging nozzle shown in FIG. 3. During the experiment, the semiconductor substrate was rotated at about 500 rpm and the swinging nozzle was swung at about 50 mm/sec. Also, water was dripped from the swinging nozzle at a rate of 2 L/min. FIG. 6 is a graph showing the thickness of the oxide film in the diametral direction. Curve “a” shown in FIG. 6 relates to the case where water was dripped from only above the center of the semiconductor substrate, and curve “b” relates to the case where water was dripped from the swinging nozzle. As apparent from the experimental data, the thickness of the oxide film is significantly increased in the central portion of the oxide film, if water is dripped from only above the center of the semiconductor substrate. On the other hand, the oxide film is rendered uniform in thickness as a whole, if water is dripped by using a swinging nozzle.

### EXAMPLE 4

In this Example, a sulfuric acid-circulating tank was used which was provided with a tank body containing sulfuric acid at 120° C. and a circulating pipe connected to the bottom of the tank body and to the top portion of the tank body for circulating sulfuric acid through the tank body. A pump for circulating the sulfuric acid was mounted on the circulating pump.

First, a 98% sulfuric acid was charged in the tank body, in which a silicon wafer treated with diluted fluoric acid was immersed for 10 minutes while circulating the sulfuric acid. Then, the wafer was removed from the tank, rinsed and dried. The thickness of the chemical oxide film formed on the silicon wafer was optically measured to found to be about 2.5 Å.

Next, a fresh 98% sulfuric acid was charged in the tank body, in which a fresh silicon wafer treated with diluted fluoric acid was immersed together with 4 silicon wafers each coated with a photoresist for 10 minutes while circulating the sulfuric acid. Then, the diluted fluoric acid-treated silicon wafer was removed from the tank, rinsed and dried. The thickness of the chemical oxide film formed on the diluted fluoric acid-treated silicon wafer was optically measured to found to be about 3.5 Å.

Further, a fresh 98% sulfuric acid was charged in the tank body, in which a fresh silicon wafer treated with diluted hydrofluoric acid was immersed together with 34 silicon wafers each coated with a photoresist for 10 minutes while circulating the sulfuric acid. Then, the diluted hydrofluoric acid-treated silicon wafer was removed from the tank, rinsed and dried. The thickness of the chemical oxide film formed on the diluted fluoric acid-treated silicon wafer was optically measured to found to be about 4.2 Å. When the number of silicon wafers coated with a photoresist was increased to 75, the thickness of the chemical oxide film formed on a silicon wafer treated with hydrofluoric acid was found to be about 7.5 Å.

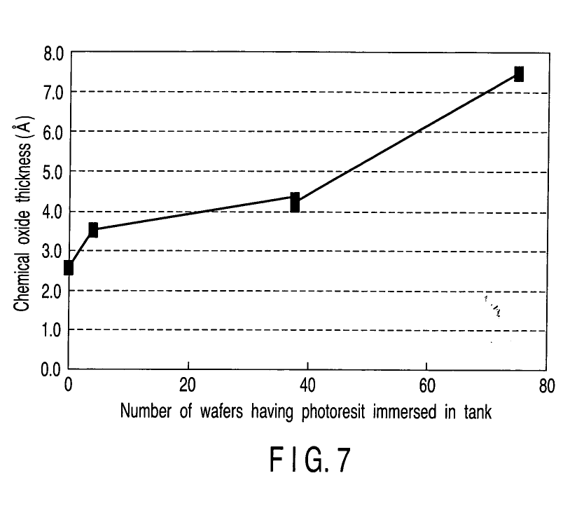

These results are shown in FIG. 7.

The results shown in FIG. 7 indicate that when sulfuric acid containing a photoresist dissolved therein is circulated at a high temperature of 120° C. with silicon wafers to be processed immersed in the sulfuric acid, the dissolved matter of the photoresist reacts with the silicon so as to change the thickness of the chemical oxide film formed on the silicon surface depending on the number of the wafers to be processed. In this processing, the thickness of the chemical oxide film is very important in controlling the thickness of very thin insulating film. If the difference in thickness of the chemical oxide amounts to about 5 Å between batches, electrical properties of the resultant devices are significantly varied. In addition, the circulating sulfuric acid tank must be made large to process wafers made large nowadays, requiring a large amount of sulfuric acid. Thus, exchanging sulfuric acid after each batch processing is costly.

Then, using a single wafer processing apparatus, sulfuric acid was applied from above from a nozzle to a sample wafer coated with a novolak resin photoresist such that the sulfuric acid was applied solely to the device surface (plane including the surface of the photoresist), and the photoresist was dissolved in about 10 minutes. The sulfuric acid dissolving the photoresist therein was recovered and disposed. Thus, the sulfuric acid applied to the wafer was always fresh, and the chemical oxide films were equally thin even when a large number of wafers are processed in this manner.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device, comprising:
selectively forming a photoresist film on an insulating film formed on a surface of a underlying semiconductor region such that the photoresist provides a masked surface region and an exposed surface region for the insulating film;
selectively removing that portion of the insulating film which corresponds to the exposed surface region to expose the underlying semiconductor region;
applying sulfuric acid to a plane including a surface of the photoresist film, with the surface of the underlying semiconductor region being exposed; and
removing the photoresist film with the sulfuric acid.

2. The method according to claim 1, wherein the sulfuric acid is dripped from a nozzle place above the photoresist film down to the plane including the surface of the photoresist film.

3. The method according to claim 1, wherein the photoresist dissolved by the dripped sulfuric acid is centrifugally separated and removed from the insulating film.

4. The method according to claim 1, wherein the sulfuric acid has a concentration not lower than 85% by weight.

5. The method according to claim 1, wherein the sulfuric acid is at a temperature of 20 to 130° C.

6. The method according to claim 1, wherein the underlying semiconductor region is provided by a semiconductor substrate, and the method further comprises forming, after removal of the photoresist film, a second insulating film on the exposed surface of the underlying semiconductor region, the second insulating film being smaller in thickness than the insulating film previously formed on the surface of the underlying semiconductor region.

7. The method according to claim 6, wherein the second insulating film has a thickness smaller than 1.2 nm.

8. The method according to claim 6, wherein, after removal of the photoresist film, the exposed semiconductor substrate is washed with water supplied form a swinging nozzle that is swung in the radial direction in a free space above the semiconductor substrate between the center and the edge of the semiconductor substrate.

9. The method according to claim 1, wherein the underlying semiconductor region is provided by a polycrystalline silicon film formed on the semiconductor substrate with an insulating film interposed therebetween.

10. The method according to claim 9, further comprising forming a semiconductor film in contact with the exposed underlying semiconductor region after removal of the photoresist film.

11. The method according to claim 10, wherein the semiconductor film is provided by a polycrystalline silicon film.

12. The method according to claim 1, wherein the sulfuric acid is free of hydrogen peroxide.
